(19) United States
(12) Patent Application Publication
(10) Pub. No.: US 2006/0223236 A1
(43) Pub. Date: Oct. 5, 2006

(54) Method of manufacturing flexible circuit substrate

(75) Inventors: Tomohiro Nomura, Nagano-shi (JP); Kazunori Abe, Nagano-shi (JP)

Correspondence Address: RANKIN, HILL, PORTER & CLARK LLP, 4080 ERIE STREET, WILLOUGHBY, OH, 44094-7836, US

(73) Assignee: Shinko Electric Industries Co., Ltd., Nagano-shi (JP)

(21) Appl. No.: 11/392,308

(22) Filed: Mar. 29, 2006

(30) Foreign Application Priority Data
Mar. 30, 2005 (JP) 2005-098938

(51) Int. Cl. H01L 21/00

(52) U.S. Cl. 438/121

(57) ABSTRACT

Connection pads and alignment marks are formed on a long metal thin plate that is carried in a longitudinal direction, and then an insulating layer for covering the connection pads is formed. Then, via holes, which are aligned and arranged on the connection pads by utilizing the alignment marks, are formed in portions of the insulating layer. Then, n-layered (n is an integer of 1 or more) wiring layers connected to the connection pads via the via holes are formed, and the connection pads and the insulating layer are exposed by removing the metal thin plate.

The present application claims foreign priority based on Japanese Patent Application No. 2005-098938, filed Mar. 30, 2005, the content of which is incorporated herein by reference.

### BACKGROUND OF THE INVENTION

1. Technical Field

The present invention relates to a method of manufacturing a flexible circuit substrate and, more particularly, a method of manufacturing a flexible circuit substrate, which is applicable in a tape package such as a tape BGA, a tape CSP, or the like.

2. Related Art

In the related art, there are the tape packages such as the tape BGA (Ball Grid Array), the tape CSP (Chip Size Package), and the like using the polyimide tape as the substrate. In an example of the method of manufacturing the tape package in the related art, as shown in FIG. 14(a), first a polyimide tape 100 on both sides of which copper (Cu) layers 102a, 102b are provided is prepared. This polyimide tape 100 is pulled out from the reel, then carried by the so-called reel-to-reel system, and then processed by various manufacturing equipments. Then, as shown in FIG. 14(b), a protection tape 104 is pasted on the lower surface side of the polyimide tape 100 to reinforce the polyimide tape 100. Then, a through hole 100x is formed to pass through the polyimide tape 100, by processing the copper layer 102a and the polyimide tape 100 by means of the laser beam machining.

Then, as shown in FIG. 14(c), a seed layer (not shown) is formed on an inner surface of the through hole 100x in the polyimide tape 100 and an upper surface of the copper layer 102a. Then, a metal layer 106 made of Cu to fill the through hole 100x in the polyimide tape 100 is formed on the Cu layer 102a by the electrolytic plating using the seed layer as a plating power feeding layer. Then, a resist film 108 is patterned on the metal layer 106, and then the metal layer 106 and the copper layer 102a are etched by using the resist film 108 as a mask. Then, the resist film 108 is removed.

Accordingly, as shown in FIG. 14(d), a wiring layer 110a connected to the copper layer 102b via the through hole 100x in the polyimide tape 100 is formed on an upper surface of the polyimide tape 100.

Then, as shown in FIG. 15(a), the protection tape 104 pasted on the lower surface side of the polyimide tape 100 is peeled off, and a new protection tape 104a is pasted on the upper surface side of the polyimide tape 100. Then, a resist film 108a is patterned on the copper layer 102b exposed from the lower surface side of the polyimide tape 100. Then, the Cu layer 102b is etched by using the resist film 108a as a mask, and then the resist film 108a is removed.

Thus, as shown in FIG. 15(b), a wiring layer 110b is formed on the lower surface side of the polyimide tape 100. Thus, the wiring layers 110a, 110b connected mutually via the through hole 100x in the polyimide tape 100 are formed on both surface sides of the polyimide tape 100 respectively. Then, as shown in FIG. 15(c), the wiring layer 110a formed on the upper surface side of the polyimide tape 100 is exposed by removing the protection tape 104a.

Then, as shown in FIG. 16(a), insulating layers 112a, 112b for covering the wiring layers 110a, 110b are formed on both surface sides of the polyimide tape 100 respectively. Then, as shown in FIG. 16(b), via holes 112x, 112y having a depth that reaches the wiring layers 110a, 110b on both surface sides of the polyimide tape 100 respectively are formed by processing the insulating layers 112a, 112b on both surface sides of the polyimide tape 100 by means of the laser respectively.

Then, as shown in FIG. 16(c), second-layer wiring layers 114a, 114b connected to the first-layer wiring layers 110a, 110b via the via holes 112x, 112y in the insulating layers 112a, 112b respectively are formed on both surface sides of the polyimide tape 100 by the semi-additive process, or the like. Then, a multi-layered wiring that is connected mutually via the through hole 100x and has a predetermined number of layers is formed on both surface sides of the polyimide tape 100 respectively, by forming repeatedly the insulating layer and the wiring layer by the similar methods.

[Patent Literature 1] JP-A-9-283925

[Patent Literature 2] JP-A-2002-190543

[Patent Literature 3] JP-A-2004-363169

[Patent Literature 4] JP-A-10-178271

However, a rigidity of the polyimide tape is originally small. Hence, when the tape is thinned to reduce a thickness of the package, the tape is broken or glued on during the reel-to-reel transfer and in some cases the polyimide tape cannot be carried satisfactorily. Also, not only the polyimide tape is expanded and contracted by the heat treatment in manufacturing steps but also an elongation easily occurs in the tape since a tension (stretching process) is applied in the transfer. Therefore, when a finer pitch between the wiring layers and an increase of the number of multiple wiring layers are advanced, the influence of expansion and contraction of the polyimide tape makes it difficult to form the desired multi-layered wiring layer while aligning the layers (the wiring layers and the via holes) mutually with high precision.

As described above, in the related art, the expansion and contraction of the polyimide tape must be considered in the alignment in forming the multi-layered wiring layer. For this reason, such a problem lies that the related art cannot easily adapt to a finer pitch between the wiring layers and an increase of the number of multiple wiring layers.

### SUMMARY OF THE INVENTION

The present invention has been made in view of the above circumstances, and it is an object of the present invention to provide a method of manufacturing a flexible circuit substrate, capable of responding easily to a finer pitch between wiring layers and an increase of the number of multiple wiring layers.

However, the present invention need not achieve the above objects, and other objects not described herein may also be achieved. Further, the invention may achieve no disclosed objects without affecting the scope of the invention.

In order to overcome the above problems, the present invention is associated with a method of manufacturing a flexible circuit substrate, which includes a step of forming connection pads and alignment marks on a long metal thin plate that is carried in a longitudinal direction; a step of forming an insulating layer to cover the connection pads; a step of forming via holes, which are aligned and arranged on the connection pads by utilizing the alignment marks, in portions of the insulating layer; a step of forming n-layered (n is an integer of 1 or more) built-up wiring layers connected to the connection pads via the via holes; and a step of exposing the connection pads and the insulating layer by removing the metal thin plate.

In the present invention, the long metal thin plate (copper thin plate, or the like) that is unwound from the reel and carried by the reel-to-reel system is used as the temporal supporting substrate. Unlike the case where the thin polyimide tape is processed by the reel-to-reel transfer, the metal thin plate is never expanded and contracted during the manufacturing step and also the trouble is hard to occur at the time of transfer since the metal thin plate has both a flexibility and some rigidity.

Then, the connection pads and the alignment marks are formed on the metal thin plate, and then the insulating layer for covering them is formed. Then, the portion of the insulating layer on the connection pad is specified by the alignment using the alignment marks on the metal thin plate, and then the via holes are formed by processing the portion of the insulating layer by means of the laser, or the like. Then, the desired built-up wiring layer connected to the connection pads via the via holes is formed to be aligned similarly.

There is no chance that the connection pads, the alignment marks, and the insulating layers connected to the metal thin plate are displaced due to the expansion and the contraction. Therefore, an alignment precision of the connection pads, the via holes, and the like can be improved remarkably rather than the case where the polyimide tape is employed.

Then, the metal thin plate as the temporal supporting substrate is removed, and thus the flexible circuit substrate employing the insulating layer as the flexible substrate can be obtained.

In this manner, in the present invention, the built-up wiring layer is formed with good positional precision by utilizing the alignment mark formed on the metal thin plate as the temporal supporting substrate, and then the flexible circuit substrate is obtained by removing the metal thin plate. Therefore, the present invention can deal easily with a finer pitch between the connection pads and the wiring layers and an increase of the number of multiple wiring layers.

In the preferred embodiment used when the semiconductor chip is mounted on the flexible circuit substrate of the present invention, the semiconductor chip is mounted on the connection portions of the uppermost wiring layer of the built-up wiring layer, and the external connection terminal is provided onto the connection pad exposed on the lower side. The stage of mounting the semiconductor chip may be executed before or after the metal thin plate is removed.

In the preferred embodiment of the present invention, the step of forming the connection pads and the alignment marks, includes a step of forming a resist film having first and second opening portions on the metal thin plate, a step of forming the connection pads and the alignment marks in the first and second opening portions respectively, by forming a metal layer on portions of the metal thin plate exposed from the first and second opening portions by an electrolytic plating, and a step of removing the resist film.

Also, if the concave portion is provided in the metal thin plate in the opening portion of the resist film, the connection pad having the projected portion that project outward can be obtained without provision of the external connection terminal.

In Patent Literatures 1 and 4, the method of manufacturing the flexible wiring substrate by forming the multi-layered wiring layer on the metal plate and then removing the metal plate is set forth. Also, in Patent Literature 3, it is set forth that the multi-layered wiring layer is formed on the metal tape (aluminum) and then the metal plate is removed.

However, in Patent Literatures 1, 3 and 4, the technology that employs the flexible metal thin plate, which is carried by the reel-to-reel system and has some rigidity, as the temporal supporting substrate and then forms the built-upwiring layer having the connection pads on the lowermost side with high alignment precision by utilizing alignment marks formed on the flexible metal thin plate is not suggested at all.

In Patent Literature 2, the technology to form the wiring layers on the long copper strip is set forth, but the copper strip is employed finally as the substrate. Therefore, it is not suggested at all that the flexible circuit substrate using the insulating layer as the substrate can be manufactured with good precision. In this manner, none of Patent Literatures 1 to 4 does not suggest the configuration of the present invention.

As described above, the method of manufacturing the flexible circuit substrate of the present invention can deal easily with a finer pitch between the wiring layers and an increase of the number of multiple wiring layers.

### BRIEF DESCRIPTION OF THE DRAWINGS

FIGS. 1(a) to (d) are sectional views (#1) showing a method of manufacturing a flexible circuit substrate according to a first exemplary, non-limiting embodiment of the present invention.

FIGS. 2(a) and (b) are plan views showing a situation that connection pads and alignment marks are formed on a long metal thin plate of the first exemplary, non-limiting embodiment of the present invention.

FIGS. 3(a) to (d) are sectional views (#2) showing the method of manufacturing the flexible circuit substrate according to the first exemplary, non-limiting embodiment of the present invention.

FIGS. 4(a) to (c) are sectional views (#3) showing the method of manufacturing the flexible circuit substrate according to the first exemplary, non-limiting embodiment of the present invention.

FIGS. 5(a) and (b) are sectional views (#4) showing the method of manufacturing the flexible circuit substrate according to the first exemplary, non-limiting embodiment of the present invention.

FIGS. 6(a) and (b) are sectional views (#5) showing the method of manufacturing the flexible circuit substrate according to the first exemplary, non-limiting embodiment of the present invention.

FIG. 7 is a sectional view showing an example in which a semiconductor chip connected to the flexible circuit substrate of the first exemplary, non-limiting embodiment of the present invention via wires.

FIGS. 8(a) to (c) are sectional views (#1) showing a method of manufacturing a flexible circuit substrate according to a second exemplary, non-limiting embodiment of the present invention.

FIGS. 9(a) to (c) are sectional views (#2) showing the method of manufacturing the flexible circuit substrate according to the second exemplary, non-limiting embodiment of the present invention.

FIG. 10 is a sectional views (#3) showing the method of manufacturing the flexible circuit substrate according to the second exemplary, non-limiting embodiment of the present invention.

FIGS. 11(a) to (c) are sectional views (#1) showing a method of manufacturing a flexible circuit substrate according to a third exemplary, non-limiting embodiment of the present invention.

FIGS. 12(a) and (b) are sectional views (#2) showing the method of manufacturing the flexible circuit substrate according to the third exemplary, non-limiting embodiment of the present invention.

FIGS. 13(a) and (b) are sectional views (#3) showing the method of manufacturing the flexible circuit substrate according to the third exemplary, non-limiting embodiment of the present invention.

FIG. 14 is a sectional view (#1) showing a method of manufacturing a tape package in the related art.

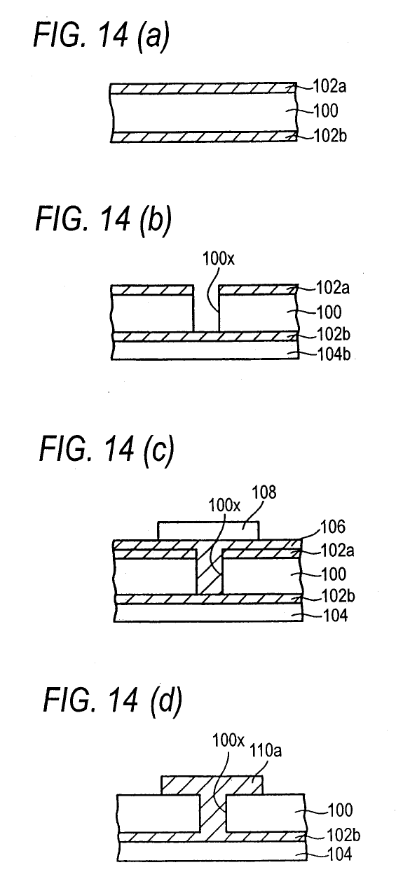

FIG. 15 is a sectional view (#2) showing the method of manufacturing the tape package in the related art.

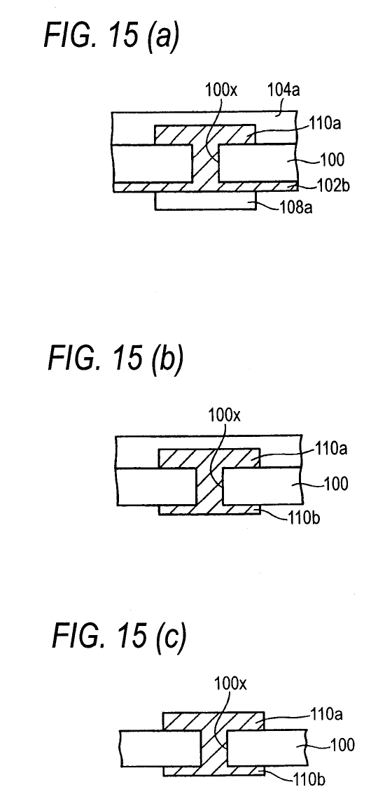

FIG. 16 is a sectional view (#3) showing the method of manufacturing the tape package in the related art.

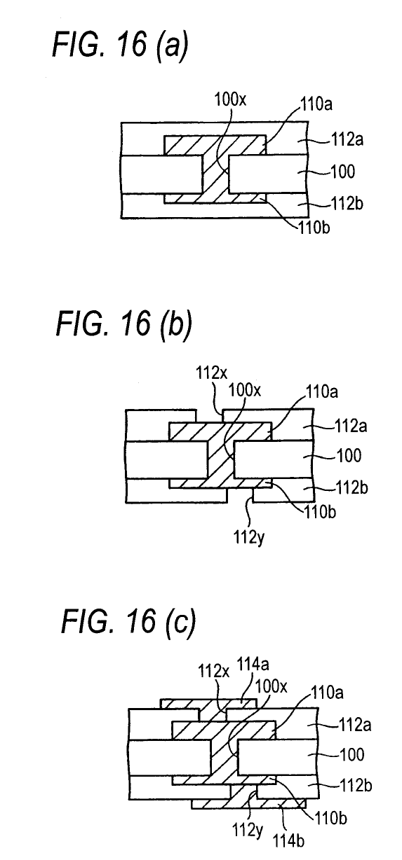

### DETAILED DESCRIPTION OF THE INVENTION

Embodiments of the present invention will be explained with reference to the accompanying drawings hereinafter.

### First Embodiment

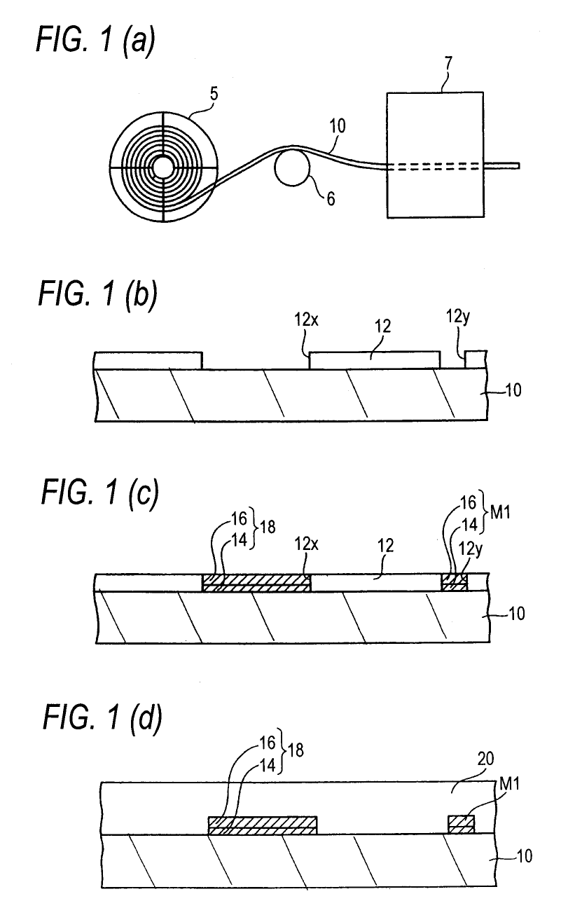

FIG. 1 to FIG. 6 are sectional views showing a method of manufacturing a flexible circuit substrate according to a first exemplary, non-limiting embodiment of the present invention. In the method of manufacturing the flexible circuit substrate of the first embodiment of the present invention, as shown in FIG. 1(a), first a long metal thin plate 10 that is unwound from a reel (winding member) 5 and carried in the longitudinal direction is prepared. As the metal thin plate 10, various metal materials can be employed, preferably a copper thin plate having a flexibility should be employed and a thickness thereof should be set to about 0.1 to 0.2 mm. Further, the metal thin plate 10 includes metal foil.

In the present embodiment, the long metal thin plate 10 that is carried by the reel-to-reel system is used as the temporary supporting substrate. The metal thin plate 10 is unwound from the reel 5 and carried into various manufacturing machines 7 while applying a tension (stretching process) by a roller 6, and then the wiring layers, the insulating layers, and the like are formed on the metal thin plate 10. The metal thin plate 10 of the present embodiment has flexibility and some rigidity. Therefore, unlike the case where the thin polyimide tape is processed by the reel-to-reel transfer, this metal thin plate 10 neither stretches by a tension if applied during the transfer nor expands and contracts by a heat treatment in manufacturing steps, and also trouble is hard to arise during the transfer. Therefore, high-precision alignment can be achieved by the photolithography or the laser beam machining, as described later.

Then, as shown in FIG. 1(b), a resist film 12 in which first and second opening portions 12x, 12y are provided is formed on the metal thin plate 10. Then, as shown in FIG. 1(c), a barrier contact layer 14 is formed by applying the gold (Au) plating and then the nickel (Ni) plating to portions of the metal thin plate 10 exposed from the first and second opening portions 12x, 12y in the resist film 12 by means of the electrolytic plating using the metal thin plate 10 as the plating power feeding path. Then, a Cu plating layer 16 is formed on the barrier contact layer 14 by the similar method. Thus, a connection pad 18 consisting of the barrier contact layer 14 and the Cu plating layer 16 is obtained. At this time, the barrier contact layer 14 and the Cu plating layer 16 are formed in the second opening portion 12y in the resist film 12 to provide a first alignment mark M1 simultaneously with formation of the connection pad 18. Then, the resist film 12 is removed. In this case, in this step, not only the connection pad 18 is formed but also the wiring layer connected to the connection pad 18 may be formed at the same time.

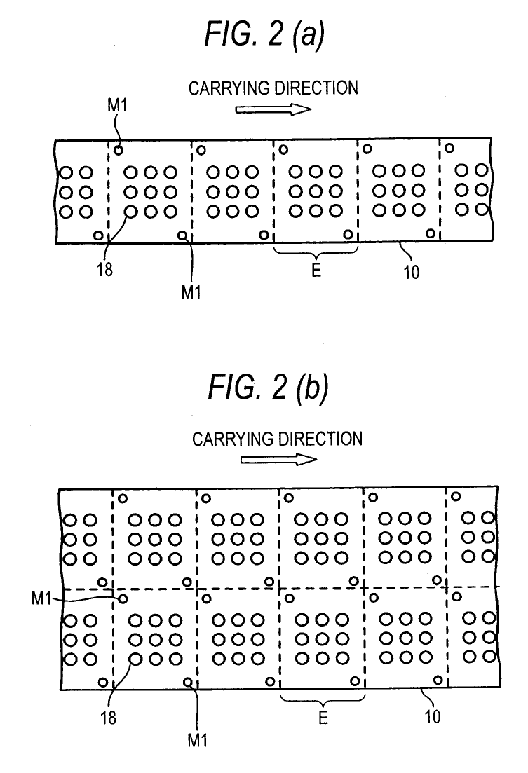

In the present embodiment, as shown in FIG. 2(a), a plurality of semiconductor chip mounting areas E are formed along the carrying direction (longitudinal direction) of the long metal thin plate 10, and the connection pads 18 and the first alignment marks M1 are formed on individual semiconductor chip mounting area E respectively. Then, as described later, a built-up wiring layer connected to the connection pads 18 of the metal thin plate 10 is formed, and then the metal thin plate 10 is removed and also external connection terminals are provided to the exposed connection pads before or after the semiconductor chip is mounted. Then, individual semiconductor devices are obtained by cutting the metal thin plate 10 along boundary portions between semiconductor chip mounting areas E.

Alternately, shown in FIG. 2(b), a plurality of semiconductor chip mounting areas E may be provided in the width direction of the long metal thin plate 10.

Then, as shown in FIG. 1(d), a first insulating layer 20 for covering the connection pads 18 and the first alignment marks M1 is formed. As the first insulating layer 20, a resin that still has the flexibility after the curing is employed. For example, an epoxy resin, a polyimide resin, or a polyphenylene ether resin is employed. As the method of forming such resin layer, there is the method of laminating a resin film on the metal thin plate 10 on which the connection pads 18 are formed and then curing the resin at a temperature of 80 to 140° C. by the thermal press. Otherwise, the resin layer may be formed by the spin coating method or the printing method.

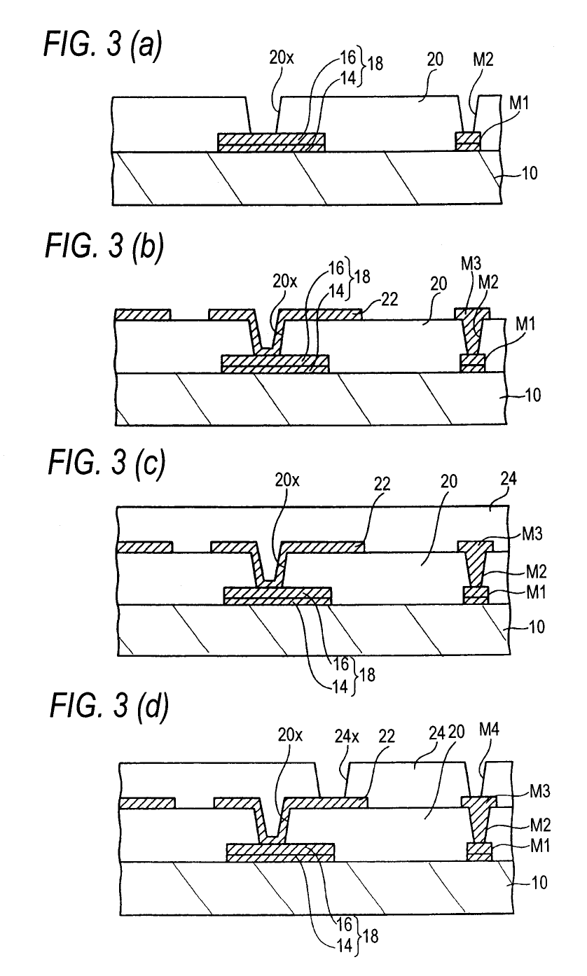

Then, as shown in FIG. 3(a), a first via hole 20x having a depth that reaches the connection pad 18 is formed, by processing a portion of the first insulating layer 20 on the connection pad 18 by means of the laser. The laser beam machining of the first insulating layer 20 is executed by utilizing the first alignment marks M1 provided on the metal thin plate 10. At this time, because the metal thin plate 10 having the rigidity to some extent is employed as the supporting substrate, the expansion and contraction is hardly generated in the metal thin plate 10, unlike the case where the polyimide tape is used as the substrate. Therefore, the disadvantage such as a displacement of the first alignment marks M1 is not caused. Also, since the first insulating layer 20 is pasted onto the metal thin plate 10, such first insulating layer 20 is never expanded and contracted. As a result, the first via hole 20x can be formed to be aligned with the connection pad 18 with high precision, and can be adapted easily to a miniaturization of the connection pad 18.

Also, in forming the first via hole 20x by the laser, a hole pattern is formed on a portion of the first insulating layer 20 on the first alignment marks M1 to provide a second alignment mark M2.

Here, the first via hole 20x may be formed by the photolithography and the etching. In this case, the first via hole 20x can be formed on the first insulating layer 20 by utilizing the first alignment marks M1 in this photolithography step in a situation that the opening portion in the resist film is aligned with the connection pad 18 with high precision.

Then, as shown in FIG. 3(b), a first wiring layer 22, which is connected to the connection pad 18 via the first via hole 20x in the first insulating layer 20, and a third alignment mark M3 are formed on the first insulating layer 20. This first wiring layer 22 is formed by the semi-additive process, for example. Particularly explaining, first a seed layer (not shown) made of Cu, or the like is formed on an inner surface of the first via hole 20x and an upper surface of the first insulating layer 20 by the electroless plating or the sputter method. Then, a resist film (not shown) in which an opening portion is provided in a portion in which the first wiring layer 22 is formed is patterned. Then, a metal (Cu) layer pattern (not shown) is formed on the seed layer in the opening portion in the resist film by the electrolytic plating utilizing the seed layer as the plating power feeding layer. Then, the first wiring layer 22 is formed by removing the resist film and then etching the seed layer while using the metal layer pattern as a mask. In the formation of the first wiring layer 22, such first wiring layer 22 can be aligned with the first via hole 20x with high precision by utilizing the second alignment mark M2. In this case, the first via hole 20x may be filled with the Cu plating.

Then, as shown in FIGS. 3(c) and (d), a second insulating layer 24 for covering the first wiring layer 22 is formed, and then a second via hole 24x and a fourth alignment mark M4 are formed by processing the portion of the second insulating layer 24 on the first wiring layer 22 by means of the laser. As the second insulating layer 24, the resin having the flexibility is employed similarly to the above first insulating layer 20. In the formation of the second via hole 24x, such second via hole 24x can be aligned with the first wiring layer 22 with high precision since the third alignment mark M3 is utilized.

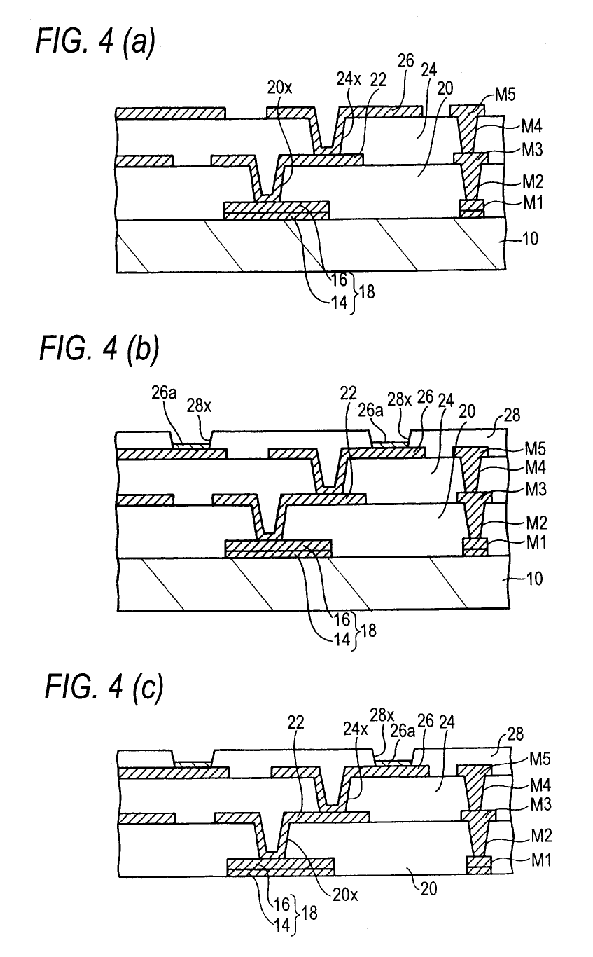

Then, as shown in FIG. 4(a), according to the similar method to the method of forming the first wiring layer 22, a second wiring layer 26 connected to the first wiring layer 22 via the second via hole 24x is formed on the second insulating layer 24. At this time, a fifth alignment mark M5 is formed simultaneously on the fourth alignment mark M4.

In the formation of the second wiring layer 26, such second wiring layer 26 can be aligned with the second via hole 24x with high precision since the fourth alignment mark M4 is utilized.

Then, as shown in FIG. 4(b), a cover coating layer 28 made of the solder resist, in which opening portions 28x are provided to portions acting as the connection portions of the second wiring layer 26, is formed. The opening portions 28x in the cover coating layer 28 are formed to be aligned with the second wiring layer 26 by using the fifth alignment mark M5. Then, connection portions 26a are formed by applying the Ni plating and then Au plating to the portions of the second wiring layer 26, which are exposed from the opening portions 28x in the cover coating layer 28.

In the above embodiment, the two-layered built-up wiring layer is formed over the connection pad 18. Here, the n-layered (n is an integer of 1 or more) built-up wiring layer may be formed.

Then, as shown in FIG. 4(c), lower surfaces of the connection pad 18 (barrier contact layer 14) and the first insulating layer 20 are exposed, by removing selectively the metal thin plate 10 from the barrier contact layer 14 of the connection pad 18 and the first insulating layer 20. In case the metal thin plate 10 is made of copper, the wet etching using an iron (III) chloride aqueous solution, a copper (II) chloride aqueous solution, an ammonium peroxodisulfate aqueous solution, or the like is employed in etching the metal thin plate 10, and the metal thin plate 10 is etched selectively with respect to the barrier contact layer 14 (Ni/Au layer) and the first insulating layer 20.

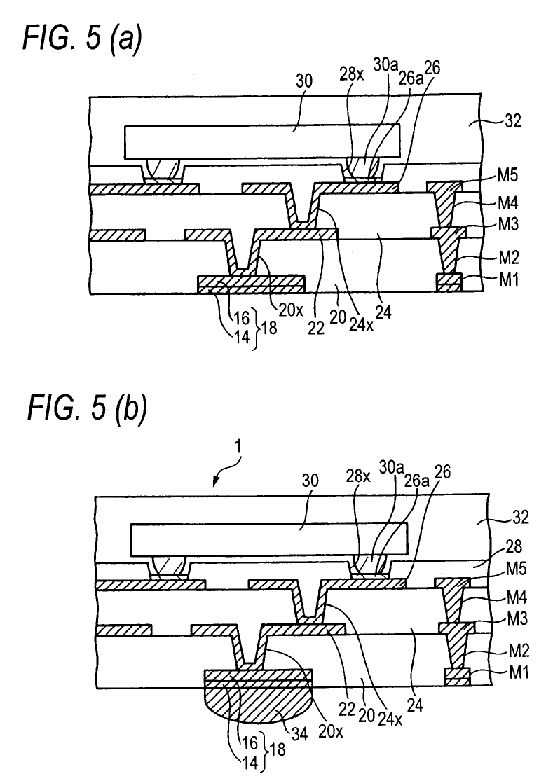

Then, as shown in FIG. 5(a), bumps 30a of a semiconductor chip 30 are flip-chip connected to the connection portions 26a of the second wiring layer 26. Then, a mold resin 32 is formed to fill a clearance below the semiconductor chip 30 and cover the semiconductor chip 30.

Then, as shown in FIG. 5(b), an external connection terminal 34 is provided by mounting the solder ball onto the connection pad 18 that is exposed from the lower surface side, or the like. Then, a resultant structure is divided into individual pieces by cutting the structure in FIG. 5(b) along boundary portions of the above semiconductor chip mounting areas E (FIGS. 2(a) and (b)).

Consequently, a flexible circuit substrate 1 according to the present embodiment, on which the semiconductor chip 30 is mounted, is obtained.

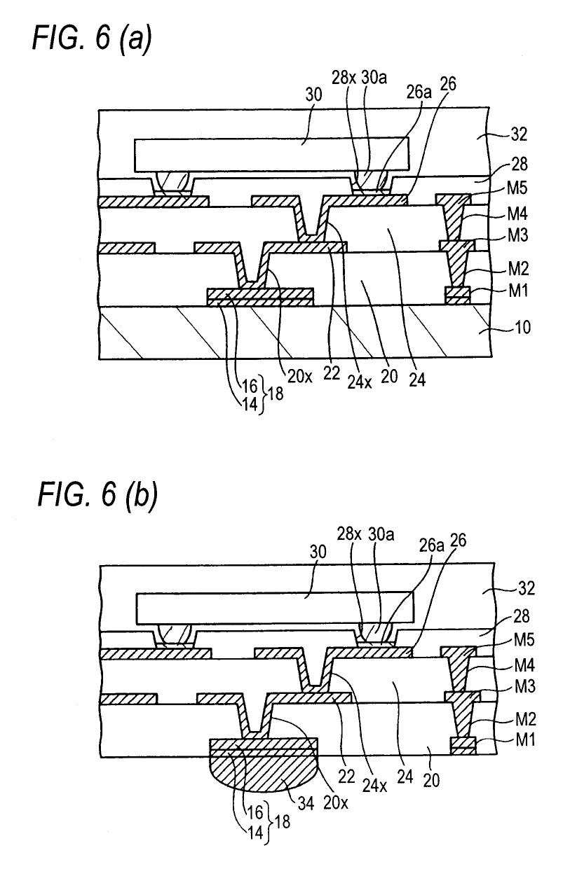

In the above embodiment, the semiconductor chip 30 is mounted after the metal thin plate 10 is removed. But the metal thin plate 10 may be removed after the semiconductor chip 30 is mounted. In other words, as shown in FIGS. 6(a) and (b), the bumps 30a of the semiconductor chip 30 may be flip-chip connected to the connection portions 26a of the second wiring layer 26 in a state that the metal thin plate 10 is kept to have the rigidity before the metal thin plate 10 is removed, then the metal thin plate 10 may be removed, and then the external connection terminals 34 may be provided to the connection pad 18 that is exposed from the lower surface side.

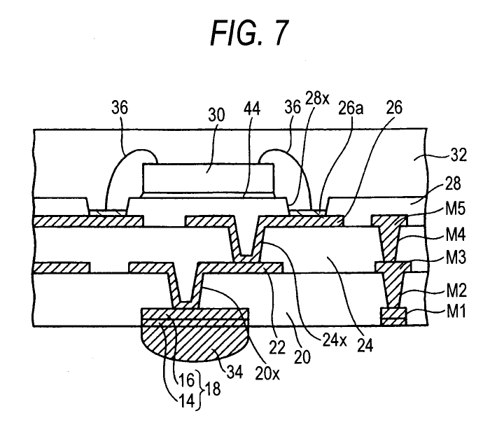

Also, as shown in FIG. 7, instead of the flip-chip connection of the semiconductor chip 30, the semiconductor chip 30 may be adhered onto the cover coating layer 28 by an adhesive layer 44 in a face-up mode to direct the connection portions thereof upward, and then the connection portions on the upper surface of the semiconductor chip 30 may be connected electrically to the connection portions 26a of the second wiring layer 26 via wires 36 by the wire bonding method. Then, the mold resin 32 for sealing the semiconductor chip 30 and the wires 36 is formed. In the present embodiment, the step of mounting the semiconductor chip 30 may be carried out before or after the metal thin plate 10 is removed.

As described above, in the method of manufacturing the flexible circuit substrate of the present embodiment, first the long metal thin plate 10 that is carried by the reel-to-reel system is prepared as the temporal supporting substrate, and then the desired built-up wiring layer containing the connection pad on the lowermost side is formed on the metal thin plate 10 with high precision. Then, the metal thin plate 10 is removed, and thus the flexible circuit substrate in which the insulating layer having the flexibility acts as the flexible substrate is obtained. The semiconductor chip may be mounted at either stage before or after the metal thin plate is removed. Then, the external connection terminal is provided to the connected pad exposed when the metal thin plate is removed.

In the manufacturing method of the present embodiment, the built-up wiring layer is formed on the metal thin plate 10 that is reel-to-reel carried and has both the flexibility and rigidity. Therefore, unlike the case where the polyimide tape is employed, the metal thin plate neither expands and contracts by a heat treatment in manufacturing steps nor stretches by a tension if applied during the transfer, and also the metal thin plate is never twisted and stuck during the transfer. In addition, the alignment marks are formed on the metal thin plate 10 and then respective layers are aligned by utilizing the alignment marks. Since the wiring layers, the alignment marks, and the insulating layers formed on the metal thin plate 10 are never displaced by the expansion and contraction, an alignment precision between the connection pads/the wiring layers and the via holes can be improved remarkably rather than the case where the polyimide tape is employed. As a result, the flexible circuit substrate of the present embodiment can conform easily to a finer pitch between wiring layers and an increase of the number of multiple wiring layers.

Herein, the first embodiment of the present invention in FIGS. 5(b), 6(b), 7 shows the flexible circuit substrate used as BGA (Ball Grid Array) where the external connection terminal 34 (solder ball) is provided on the connection pad 18. However, the present invention is not limited to this, and the flexible circuit substrate of the present invention can be used as LGA (Land Grid Array). In the case where the flexible circuit substrate is used as LGA, the solder ball is not provided and the connection pad 18 itself is used as the external connection terminal.

### Second Embodiment

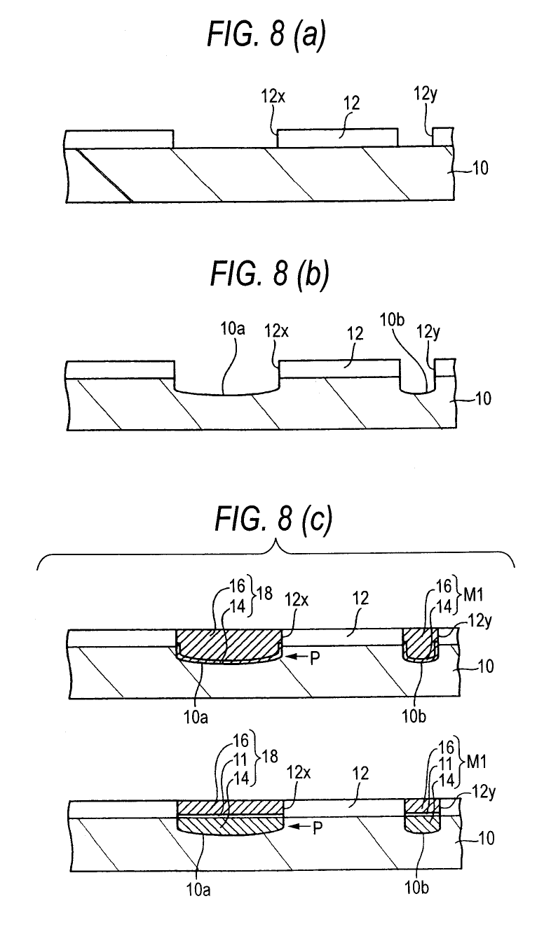

FIG. 8 to FIG. 10 are sectional views showing a method of manufacturing a flexible circuit substrate according to a second exemplary, non-limiting embodiment of the present invention. A difference of the second embodiment from the first embodiment resides in that a concave portion is provided to the portion of the metal thin plate on which the connection pad is arranged and then a projected portion (external connection terminal) connected to the connection pad is formed simultaneously in forming the connection pad. In the second embodiment, detailed explanations of the same steps as those in the first embodiment will be omitted herein.

In the method of manufacturing the flexible circuit substrate of the second embodiment, like the first embodiment, as shown in FIG. 8(a), first the resist film 12 in which the first and second opening portions 12x, 12y are provided is formed on the metal thin plate 10. Then, as shown in FIG. 8(b), a first concave portion 10a used to form the projected portion of the connection pad and a second concave portion 10b used to form the alignment mark are formed, by etching the portions of the metal thin plate 10 exposed from the first and second opening portions 12x, 12y while using the resist film 12 as a mask.

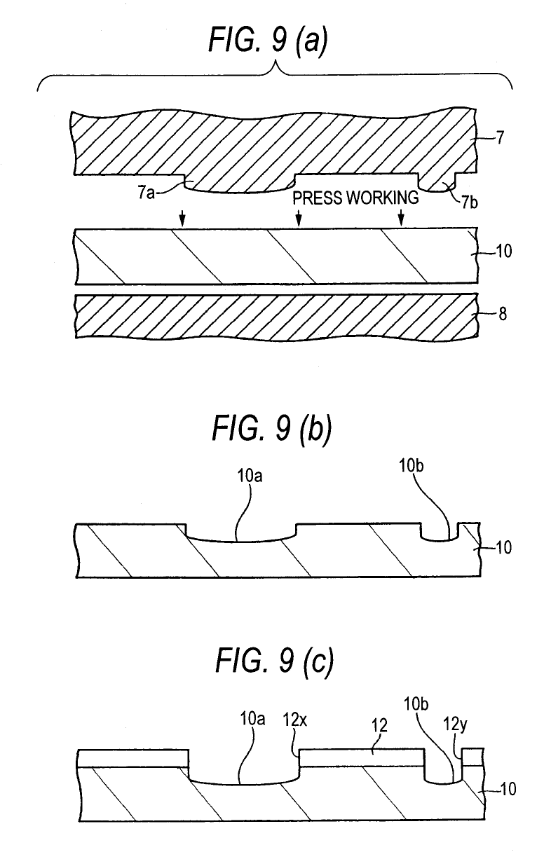

Alternately, the concave portions 10a, 10b may be formed on the metal thin plate 10 by the press working in place of the photolithography and the etching. In more detail, as shown in FIG. 9(a), the metal thin plate 10 is carried into the die unit having an upper die 7, on which convex portions 7a, 7b are provided, and a lower die 8, and then the metal thin plate 10 is pressed by the die unit. Thus, as shown in FIG. 9(b), the first concave portion 10a and the second concave portion 10b are formed on the metal thin plate 10. Then, as shown in FIG. 9(c), the resist film 12 in which the opening portions 12x, 12y are provided on the first and second concave portions 10a, 10b in the metal thin plate 10 respectively is formed. In this manner, even if the resist film 12 is patterned after the press working is applied to the metal thin plate 10, the structure similar to that shown in FIG. 8(b) can be obtained.

Then, as shown in an upper view in FIG. 8(c), the barrier contact layers 14 are formed, by applying the Au plating and then Ni plating to the portions of the metal thin plate 10, which are exposed from the first and second opening portions 12x, 12y in the resist film 12, by means of the electrolytic plating using the metal thin plate 10 as the plating power feeding path. Then, the Cu plating layer 16 is formed on the barrier contact layers 14 by the similar method to bury the concave portions 10a, 10b in the metal thin plate 10 and the opening portions 12x, 12y in the resist film 12. Thus, the connection pad 18 is constructed by the barrier contact layers 14 and the Cu plating layer 16, and the connection pad 18 is formed in a state that a projected portion P is provided on the metal thin plate 10 side. At this time, the barrier contact layers 14 and the Cu plating layer 16 are also formed in the second opening portion 12y in the resist film 12 simultaneously with the formation of the connection pad 18 to give the first alignment mark M1. Then, the resist film 12 is removed.

As other materials of the barrier contact layers 14, a laminated film such as a gold/nickel layer (combination of a gold layer and a nickel layer), a gold/palladium/nickel layer (combination of a gold layer, a palladium layer and a nickel layer), a palladium/nickel layer (combination of a palladium layer and a nickel layer), a solder/nickel layer (combination of solder layer and a nickel layer), or the like, each laminated from the bottom, or a single-layer film such as a nickel layer, a gold layer, a palladium layer, or the like may be employed.

Alternately, as shown in a lower view in FIG. 8(c), the barrier contact layers 14 may be formed by filling a solder layer in the first and second concave portions 10a, 10b in the metal thin plate 10, and then the Cu plating layer 16 may be formed in the first and second opening portions 12x, 12y in the resist film 12 via a nickel layer 11.

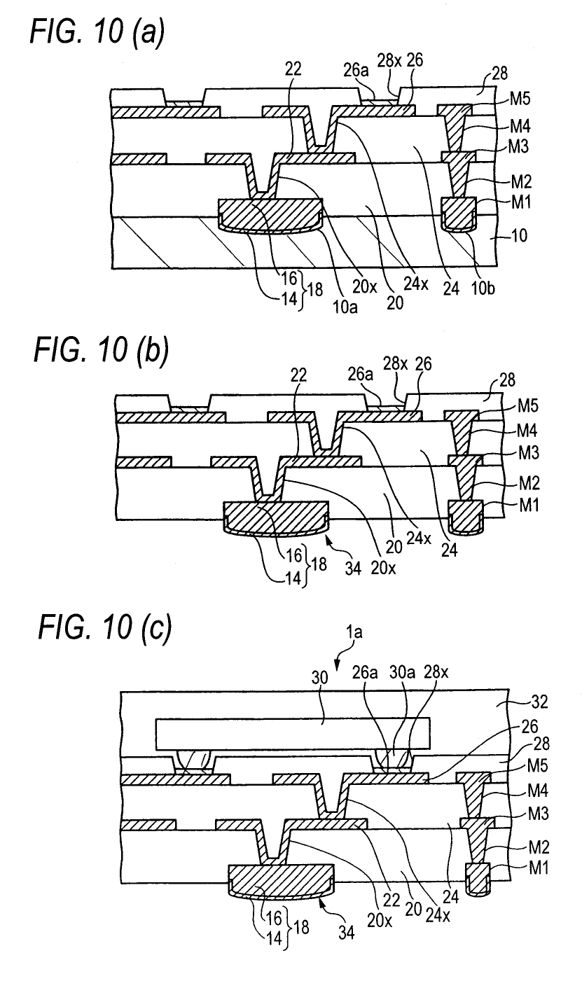

Then, as shown in FIG. 10(a), a built-up wiring layer containing the first and second wiring layers 22, 26 connected to the connection pad 18 is formed in a high-precision aligned state, by executing the steps shown in FIG. 1(d) and FIG. 3(a) to FIG. 4(b) in the first embodiment. Then, as shown in FIG. 10(b), the metal thin plate 10 is removed selectively from the connection pad 18 and the first insulating layer 20. Thus, the projected portion P of the connection pad 18 buried in the first concave portion 10a in the metal thin plate 10 is exposed to protrude from the lower surface of the first insulating layer 20, and the external connection terminal 34 is given.

Then, as shown in FIG. 10(c), the bumps 30a of the semiconductor chip 30 are flip-chip connected to the connection portions 26a of the second wiring layer 26, and then the mold resin 32 for sealing the semiconductor chip 30 is formed. Then, a resultant structure is divided into individual pieces by cutting the structure in FIG. 10(c) along the boundary portions of the above semiconductor chip mounting areas E (FIGS. 2(a) and (b)).

Consequently, a flexible circuit substrate 1a according to the second embodiment is obtained.

In this case, as explained in the first embodiment, the semiconductor chip 30 with the metal thin plate 10 to have the rigidity may mounted, and the metal thin plate 10 may be removed thereafter. Also, as explained in FIG. 7 in the first embodiment, the semiconductor chip 30 may be face-up mounted and then the semiconductor chip 30 and the connection portions 26a of the second wiring layer 26 may be connected mutually via the wires 36.

The second embodiment can achieve the same advantages as those in the first embodiment. In addition to them, there is no need to form particularly the external connection terminal in the second embodiment. This is because the connection pad 18 having the projected portion P, which projects downward from the circuit substrate, acts as the external connection terminal 34 by providing the concave portion 10a to the metal thin plate 10 in the opening portion 12x in the resist film 12. In case the solder layer is employed as the barrier contact layer 14, the step of bonding the solder ball as the external connection terminal can be omitted because the solder layer can act as a substitute for the solder ball. In particular, as shown in a lower view of FIG. 8(c), when the solder layer is filled into the concave portion 10a in the metal thin plate 10, the solder layer projected from the lower surface of the first insulating layer 20 can be formed. Such projected solder layer can be used favorably as the external connection terminal.

### Third Embodiment

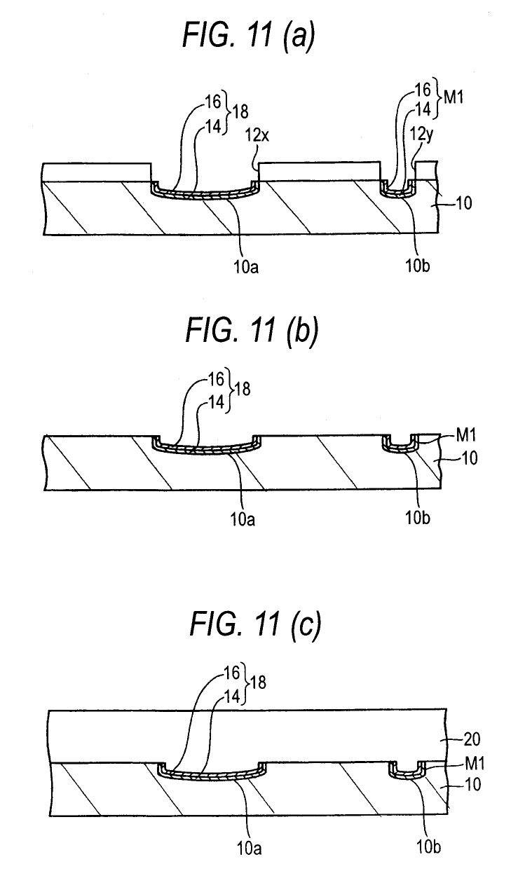

FIG. 11 to FIG. 13 are sectional views showing a method of manufacturing a flexible circuit substrate according to a third exemplary, non-limiting embodiment of the present invention. A difference of the third embodiment from the second embodiment is that the metal layers are not filled in the concave portions in the metal thin plate but formed like a layer and then the resin is filled in remaining spaces of the concave portions. In the third embodiment, detailed explanation of the same steps as those in the first and second embodiments will be omitted herein.

First, as shown in FIG. 11(a), the resist film 12 in which the first and second opening portions 12x, 12y are provided is patterned, as in FIG. 8(b), by the similar method to the second embodiment. Then, the first and second concave portions 10a, 10b are formed in the metal thin plate 10. Then, the barrier contact layer 14 and the Cu plating layer 16 are formed sequentially in the first and second concave portions 10a, 10b in the metal thin plate 10. In the third embodiment, the barrier contact layer 14 and the Cu plating layer 16 are not filled in the concave portions 10a, 10b in the metal thin plate 10 but formed like a layer. At this time, the first alignment mark M1 consisting of the barrier contact layer 14 and the Cu plating layer 16 is formed simultaneously in the second concave portion 10b in the metal plate 10. Then, as shown in FIG. 11(b), the resist film 12 is removed.

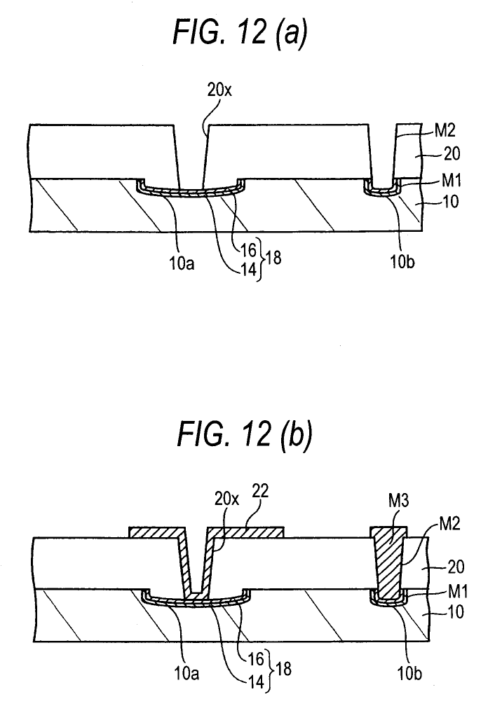

Then, as shown in FIG. 11(c), the first insulating layer 20 is formed by pasting a resin film on an upper surface of the structure in FIG. 11(b), or the like. At this time, the first and second concave portions 10a, 10b in the metal thin plate 10 are buried by the first insulating layer 20 and their upper surfaces are planarized. Then, as shown in FIG. 12(a), the first via hole 20x having a depth that reaches the connection pad 18 is formed, by processing the portion of the first insulating layer 20 on the connection pad 18 by means of the laser, or the like while aligning by utilizing the first alignment mark M1. At this time, the second alignment mark M2 is formed in the portion of the first insulating layer 20 on the first alignment mark M1. Then, as shown in FIG. 12(b), the first wiring layer 22 connected to the connection pad 18 via the first via hole 20x is formed on the first insulating layer 20 to be aligned with the connection pad. At this time, the third alignment mark M3 is also formed on the second alignment mark M2.

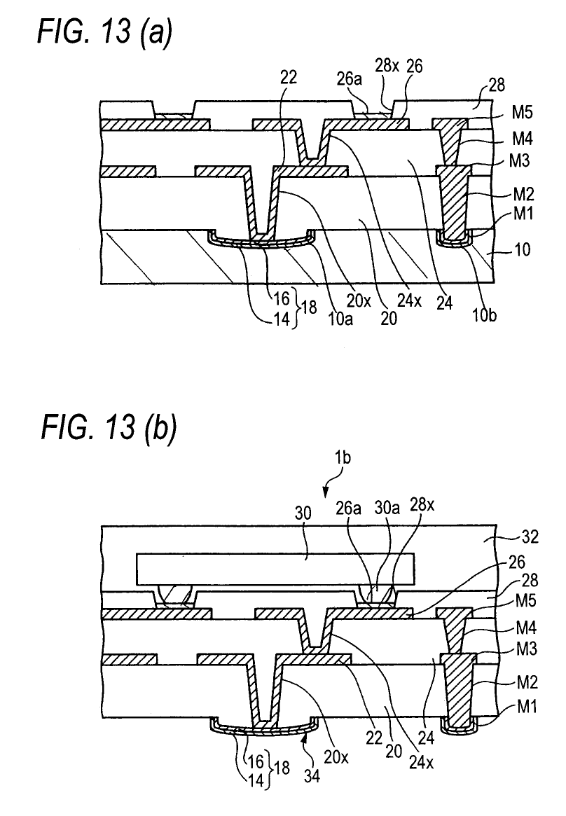

Then, as shown in FIG. 13(a), the built-up wiring layer containing the second wiring layer 26 connected to the first wiring layer 22 is formed in its aligned condition, by executing the steps shown in FIG. 3(c) to FIG. 4(b) in the first embodiment. Then, as shown in FIG. 13(b), the metal thin plate 10 is removed selectively from the connection pad 18 and the first insulating layer 20. Accordingly, the connection pad 18 formed on the bottom portion of the first concave portion 10a of the metal thin plate 10 is exposed to project from the lower surface of the first insulating layer 20, and then serves as the external connection terminal 34. In this way, the external connection terminal 34 in the third embodiment is constructed by forming the connection pad 18 like a layer on the surface of the bump formed of the first insulating layer 20.

Then, the bumps 30a of the semiconductor chip 30 are flip-chip connected to the connection portions 26a of the second wiring layer 26, and then the mold resin 32 for sealing the semiconductor chip 30 is formed. Then, a resultant structure is divided into individual pieces by cutting the structure in FIG. 13(b) along the boundary portions of the semiconductor chip mounting areas E (FIGS. 2(a) and (b)). Consequently, a flexible circuit substrate 1b according to the third embodiment is obtained.

In this case, as explained in the first embodiment, the semiconductor chip 30 with the metal thin plate 10 to have the rigidity may be mounted, and then the metal thin plate 10 may be removed. Also, the semiconductor chip 30 may be face-up mounted and then the semiconductor chip 30 and the connection portions 26a of the second wiring layer 26 may be connected mutually via the wires 36.

In the third embodiment, like the second embodiment, there is no need to provide particularly the external connection terminal. Furthermore, in the third embodiment, there is no need to fill the metal layer in the overall concave portions 10a, 10b in the metal thin plate 10 and the overall opening portions 12x, 12y in the resist film 12 by the plating process. Therefore, a time required to apply the plating process can be reduced, and also a production cost can be reduced rather than the second embodiment.

It will be apparent to those skilled in the art that various modifications and variations can be made to the described preferred embodiments of the present invention without departing from the spirit or scope of the invention. Thus, it is intended that the present invention cover all modifications and variations of this invention consistent with the scope of the appended claims and their equivalents.

I/we claim:

1. A method of manufacturing a flexible circuit substrate, comprising:
forming a connection pad and an alignment mark on a long metal thin plate that is carried in a longitudinal direction;
forming an insulating layer to cover the connection pad;
forming a via hole, which is aligned and arranged on the connection pad by utilizing the alignment mark, in a portion of the insulating layer; and
forming n-layered (n is an integer of 1 or more) wiring layers connected to the connection pad via the via hole.

2. A method of manufacturing a flexible circuit substrate, according to claim 1, further comprising:
exposing the connection pad and the insulating layer by removing the metal thin plate.

3. A method of manufacturing a flexible circuit substrate, according to claim 1, wherein the step of forming the connection pad and the alignment mark, includes
forming a resist film having first and second opening portions on the metal thin plate,
forming the connection pad and the alignment mark in the first and second opening portions respectively, by forming a metal layer on portions of the metal thin plate exposed from the first and second opening portions by an electrolytic plating, and
removing the resist film.

4. A method of manufacturing a flexible circuit substrate, according to claim 2, wherein the step of forming the connection pad and the alignment mark, includes
forming a resist film having first and second opening portions on the metal thin plate,
forming the connection pad and the alignment mark in the first and second opening portions respectively, by forming a metal layer on portions of the metal thin plate exposed from the first and second opening portions by an electrolytic plating, and
removing the resist film.

5. A method of manufacturing a flexible circuit substrate, according to claim 1, wherein the step of forming the via hole is executed by a laser beam machining.

6. A method of manufacturing a flexible circuit substrate, according to claim 4, wherein, in the step of forming the connection pad and the alignment mark, a barrier contact layer acting as an etching stop film in the step of removing the metal thin plate is formed under the metal layer, and
in the step of removing the metal thin plate, the metal thin plate is removed from the barrier contact layer and the insulating layer.

7. A method of manufacturing a flexible circuit substrate, according to claim 2, after the step of removing the metal thin plate, further comprising:
providing a connection terminal, which projects outward, to the exposed connection pad.

8. A method of manufacturing a flexible circuit substrate, according to claim 4, after the step of forming the resist film having the first and second opening portions on the metal thin plate, further comprising:
providing concave portions by etching the metal thin plate exposed from the opening portions;
wherein the connection pad is formed to have projected portion as a connection terminal, by removing the metal thin plate.

9. A method of manufacturing a flexible circuit substrate, according to claim 4, wherein concave portions formed on portions corresponding to the first and second opening portions in the resist film by a press working are provided to the metal thin plate,
in the step of forming the resist film having the first and second opening portions, opening portions of the resist film are formed in the concave portions of the metal thin plate, and
the connection pad is formed to have a projected portion acting as a connection terminal, by removing the metal thin plate.

10. A method of manufacturing a flexible circuit substrate, according to claim 2, before the step of removing the metal thin plate, further comprising:
forming an cover coating layer in which an opening portion is provided on a connection portion of an uppermost wiring layer of the wiring layer.

11. A method of manufacturing a flexible circuit substrate, according to claim 10, after the step of removing the metal thin plate, further comprising:
connecting a semiconductor chip to the connection portion of the uppermost wiring layer of the wiring layer.

12. A method of manufacturing a flexible circuit substrate, according to claim 10, before the step of removing the metal thin plate but after the step of forming the cover coating layer, further comprising:
connecting a semiconductor chip to the connection portion of the uppermost wiring layer of the wiring layer.

13. A method of manufacturing a flexible circuit substrate, according to claim 1, wherein the insulating layer has a flexibility.

14. A method of manufacturing a flexible circuit substrate, according to claim 6, wherein the metal thin plate and the metal layer are made of copper, and the barrier contact layer is made of any one selected from a group consisting of a combination of a nickel layer and a gold layer, a combination of a gold layer and a nickel layer, a combination of a gold layer, a palladium layer and a nickel layer, a nickel layer, a gold layer, a palladium layer, and a combination of a solder layer and a nickel layer.

15. A flexible circuit substrate, comprising:
a long metal thin plate;
a connection pad and an alignment mark formed on the metal thin plate;
an insulating layer covering the connection pad and having a via hole, which is aligned and arranged on the connection pad, in a portion of the insulating layer; and
n-layered (n is an integer of 1 or more) wiring layers formed on the insulating layer and connected to the connection pad via the via hole.

16. A flexible circuit substrate, according to claim 15, further comprising:
an cover coating layer formed on an uppermost wiring layer of the wiring layer so that an opening portion of the cover coating layer is provided on a connection portion of the uppermost wiring layer of the wiring layer.

17. A flexible circuit substrate, according to claim 16, further comprising:
a semiconductor chip connected to the connection portion of the uppermost wiring layer of the wiring layer.
